(19) United States
(12) Patent Application Publication
(10) Pub. No.: US 2013/0000700 A1
(43) Pub. Date: Jan. 3, 2013

(54) SOLAR CELL AND MANUFACTURING METHOD OF THE SAME

(75) Inventor: Dong Keun Lee, Seoul (KR)

(73) Assignee: LG INNOTEK. LTD., Seoul (KR)

(21) Appl. No.: 13/634,440

(22) PCT Filed: Oct. 6, 2011
(86) PCT No.: PCT/KR11/07397

§ 371 Date: Sep. 12, 2012

(30) Foreign Application Priority Data
Jan. 24, 2011 (KR) 10-2011-0006989

(51) Int. Cl. H01L 31/0224; H01L 31/05; H01L 31/18

(52) U.S. Cl. 136/249; 136/256; 438/98; 257/E31.124

(57) ABSTRACT

Disclosed are a solar cell and a manufacturing method of the same. The solar cell includes a substrate; a back electrode layer on the substrate; a light absorbing layer including a second perforation hole on the back electrode layer; a window layer on the light absorbing layer; and a barrier layer between the substrate and the back electrode layer.

### TECHNICAL FIELD

The embodiment relates to a solar cell and a manufacturing method of the same.

### BACKGROUND ART

A solar cell converts solar energy into electric energy. As the demand for solar energy is recently increased, the solar cell is commercially used in various fields.

The solar cell is manufactured by sequentially forming a substrate including sodium, a back electrode layer, a light absorbing layer and a window layer and then forming a grid electrode thereon. The light absorbing layer includes a CIGS compound. As the CIGS compound is formed on the back electrode layer, a MoSe₂ layer is formed between the back electrode layer and the light absorbing layer.

The MoSe₂ layer may increase interfacial adhesive force between the back electrode layer and the light absorbing layer. However, since the MoSe₂ layer has resistance higher than that of the back electrode layer, contact resistance between the window layer and the back electrode layer may increase, so the efficiency of the solar cell may be lowered.

### DISCLOSURE OF INVENTION

### Technical Problem

The embodiment provides a solar cell capable of improving contact resistance between a back electrode layer and a window layer and interfacial adhesive force between the back electrode layer and a light absorbing layer, and a manufacturing method of the same.

### Solution to Problem

A solar cell according to the embodiment includes a substrate; a back electrode layer on the substrate; a light absorbing layer including a second perforation hole on the back electrode layer; a window layer on the light absorbing layer; and a barrier layer between the substrate and the back electrode layer.

A method of manufacturing a solar cell according to the embodiment includes forming a barrier layer on a substrate; forming a back electrode layer on the substrate and the barrier layer; forming a light absorbing layer on the back electrode layer and forming an ohmic layer between the back electrode layer and the light absorbing layer; and forming a window layer on the light absorbing layer.

A solar cell module according to the embodiment includes a plurality of solar cells, wherein each solar cell includes a back electrode layer including a first perforation hole on a substrate; a light absorbing layer including a second perforation hole on the back electrode layer; a window layer on the light absorbing layer; a barrier layer between the substrate and the back electrode layer; and an ohmic layer between the back electrode layer and the light absorbing layer.

### Advantageous Effects of Invention

According to the solar cell of the embodiment, the ohmic layer is formed between the back electrode layer and the light absorbing layer, so that the interfacial adhesive force between the back electrode layer and the light absorbing layer can be improved.

In addition, according to the solar cell of the embodiment, the barrier layer is formed between the substrate and the back electrode layer, so that the ohmic layer (MoSe₂ layer) is not formed in the region where the back electrode layer is connected to the window layer. Thus, the window layer can be electrically connected to the back electrode layer having contact resistance higher than that of the ohmic layer, so that the efficiency of the solar cell can be improved.

### BRIEF DESCRIPTION OF DRAWINGS

FIG. 1 is a plan view of a solar cell module according to the embodiment;

FIG. 2 is a sectional view showing a solar cell according to the embodiment;

FIG. 3 is a sectional view showing a solar cell on the basis of a barrier layer according to the embodiment;

FIGS. 4 and 5 are sectional views showing the function of a barrier layer according to the embodiment; and

FIGS. 6 to 13 are sectional views showing the manufacturing procedure for a solar cell according to the embodiment.

### MODE FOR THE INVENTION

In the description of the embodiments, it will be understood that, when a panel, a wire, a cell, a device, a surface or a pattern is referred to as being “on” or “under” another panel, another wire, another cell, another device, another surface or another pattern, it can be “directly” or “indirectly” on the other panel, wire, cell, device, surface or pattern, or one or more intervening layers may also be present. Such a position will be described with reference to the drawings. The thickness and size of each element shown in the drawings may be exaggerated and may not utterly reflect an actual size.

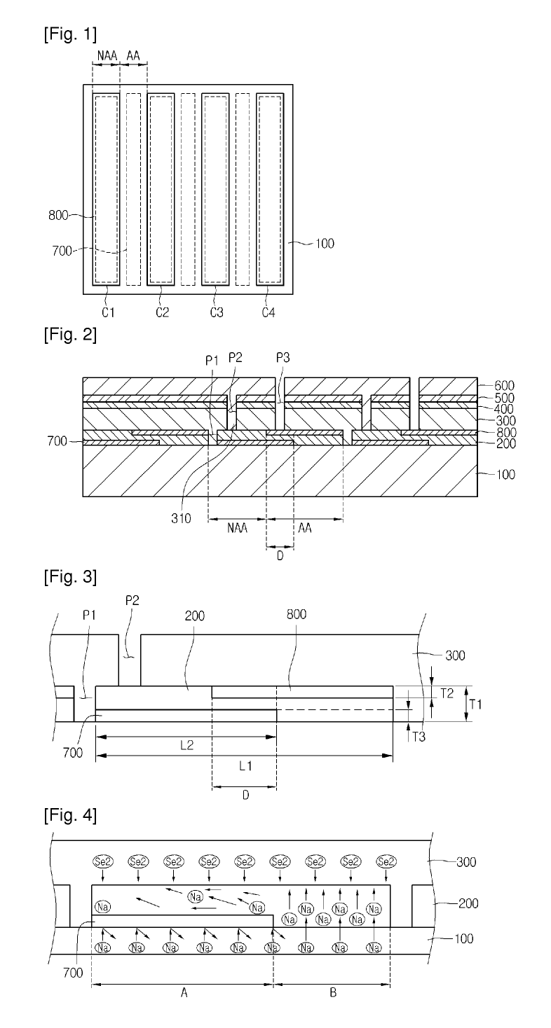

FIG. 1 is a plan view of a solar cell module according to the embodiment. The solar cell module includes a plurality of solar cells C1, C2, C3 . . . and Cn.

Referring to FIG. 1, a substrate 100 of the solar cell module includes active areas AA and non-active areas NAA. Although the active areas AA and the non-active areas NAA are arranged in the form of a stripe pattern in FIG. 1, the embodiment is not limited thereto. The active areas AA and the non-active areas NAA may be variously arranged. For instance, the active areas AA and the non-active areas NAA may be arranged in the form of a matrix.

The solar cells C1, C2, C3 . . . and Cn are disposed in the active areas AA. In detail, the active areas AA are distinguished from the non-active areas NAA by the solar cells C1, C2, C3 . . . and Cn.

In addition, each active area AA may include an ohmic layer 800. In detail, according to the solar cell module of the embodiment, the ohmic layer 800 is formed in each active area AA so that interfacial adhesive force between a back electrode layer 200 and a light absorbing layer 300 can be improved.

The non-active areas NAA are disposed between the active areas AA, respectively. That is, non-active areas NAA are disposed alternately with the active areas AA. The non-active areas NAA may be transparent. That is, since the solar cells C1, C2, C3 . . . and Cn are not disposed in the non-active areas NAA, light may transmit through the non-active areas NAA.

In addition, each non-active area NAA may include a wire to connect the solar cells C1, C2, C3 . . . and Cn with each other. For instance, a window layer of each cell and a back electrode layer of adjacent cell are connected with each other by a connection wire 310 disposed in each non-active area NAA.

Each non-active area NAA may include a barrier layer 700. In detail, the barrier layer 700 is formed on each non-active area NAA. According to the solar cell module of the embodiment, since the barrier layer 700 is formed on each non-active area NAA, the ohmic layer 800 may not be formed in the non-active areas NAA. Therefore, the window layer of each cell can be electrically connected to the back electrode layer 200 having contact resistance higher than that of the ohmic layer 800 by the connection wire 310.

Although FIG. 1 shows the barrier layer 700 separated from the ohmic layer 800, the embodiment is not limited thereto. The barrier layer 700 may partially overlap with the ohmic layer 800. For instance, referring to FIG. 2, the barrier layer 700 may be formed on a part of the active areas AA as well as the non-active areas NAA. In addition, the ohmic layer 800 may be formed on a part of the non-active areas NAA as well as the active areas AA. Thus, the barrier layer 700 may partially overlap with the ohmic layer 800, which will be described later in more detail when explaining the solar cell.

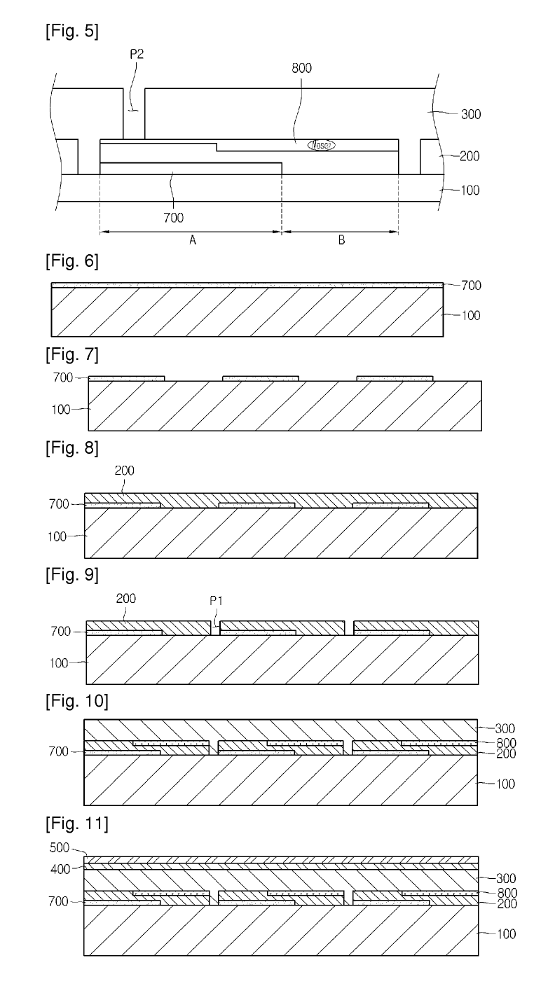

FIG. 2 is a sectional view showing the solar cell according to the embodiment and FIG. 3 is a sectional view showing the solar cell on the basis of the barrier layer according to the embodiment. In addition, FIGS. 4 and 5 are sectional views showing the function of the barrier layer according to the embodiment.

Referring to FIG. 2, the solar cell according to the embodiment includes the substrate 100 as well as the back electrode layer 200, the light absorbing layer 300, a buffer layer 400, a high-resistance buffer layer 500 and a window layer 600, which are sequentially formed on the substrate 100. In addition, the solar cell according to the embodiment includes the barrier layer 700 interposed between the substrate 100 and the back electrode layer 200 and the ohmic layer 800 selectively disposed between the back electrode layer 200 and the light absorbing layer 300.

The substrate 100 has a plate shape to support the back electrode layer 200, the light absorbing layer 300, the buffer layer 400, the high-resistance buffer layer 500, the window layer 600, the barrier layer 700 and the ohmic layer 800.

The substrate 100 may be transparent. In addition, the substrate 100 may be rigid or flexible.

The substrate 100 may include an insulating material. For instance, the substrate 100 may be a glass substrate, a plastic substrate or a metal substrate. In detail, the substrate 100 may be a soda lime glass substrate including a sodium component. In addition, the substrate 100 may include ceramic, such as alumina, stainless steel or polymer having flexibility.

The back electrode layer 200 is disposed on the substrate 100. The back electrode layer 200 is a conductive layer. The back electrode layer 200 may include one of Mo, Au, Al, Cr, W and Cu, but the embodiment is not limited thereto. Among the above elements, Mo has the thermal expansion coefficient similar to that of the substrate 100, so the adhesive property is improved and the back electrode layer 200 may not be delaminated from the substrate 100. In addition, Mo may satisfy properties required for the back electrode layer 200.

The back electrode layer 200 may include at least two layers, which are formed by using the same metal or different metals.

The back electrode layer 200 includes first perforation holes P1. That is, the back electrode layer 200 is patterned by the first perforation holes P1. In addition, the first perforation holes P1 can be variously arranged in the form of a stripe as shown in FIG. 2 or a matrix. The first perforation hole P1 may have a width of about 80 μm to about 200 μm, but the embodiment is not limited thereto.

The light absorbing layer 300 is disposed on the back electrode layer 200. The light absorbing layer 300 includes the group I-III-VI compound. For instance, the light absorbing layer 300 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure.

The buffer layer 400 is disposed on the light absorbing layer 300. The buffer layer 400 may attenuate the energy gap difference between the light absorbing layer 300 and the window layer 600, which will be described later.

In addition, the buffer layer 400 may include CdS, ZnS, InXSY or InXSeYZn(O,OH). The buffer layer 400 may have the thickness in the range of about 50 nm to about 150 nm and the energy bandgap in the range of about 2.2 eV to about 2.4 eV.

The high-resistance buffer layer 500 is disposed on the buffer layer 400. The high-resistance buffer layer 500 has high resistance, so that the high-resistance buffer layer 500 can prevent the insulation and the impact damage with respect to the window layer 600.

The high-resistance buffer layer 500 may include i-ZnO, which is not doped with impurities. The high-resistance buffer layer 500 may have the energy bandgap in the range of about 3.1 eV to about 3.3 eV. The high-resistance buffer layer 500 can be omitted.

The light absorbing layer 300, the buffer layer 400 and the high-resistance buffer layer 500 may include second perforation holes P2. That is, the second perforation holes P2 are formed through the light absorbing layer 300, the buffer layer 400 and the high-resistance buffer layer 500. The back electrode layer 200 is partially exposed through the second perforation holes P2. The second perforation hole P2 may have a width of about 80 μm to about 200 μm, but the embodiment is not limited thereto.

The second perforation hole P2 may be filled with a material identical to a material for the window layer 600 so that the connection wire 310 is formed. The connection wire 310 can electrically connect the window layer 600 to the back electrode layer 200.

The window layer 600 may include a transmissive conductive material. In addition, the window layer 600 may have the characteristic of an n type semiconductor. The window layer 600 and the buffer layer 400 may form an n type semiconductor layer so the PN junction can be formed in association with the light absorbing layer 400 serving as a p type semiconductor layer. For instance, the window layer 600 may include aluminum-doped zinc oxide (AZO). The window layer 600 may have the thickness in the range of about 100 nm to about 500 nm.

The window layer 600, the high-resistance buffer layer 500, the buffer layer 400 and the light absorbing layer 300 may include third perforation holes P3. That is, the third perforation holes P3 are formed through the window layer 600, the high-resistance buffer layer 500, the buffer layer 400 and the light absorbing layer 300. The back electrode layer 200 is partially exposed through the third perforation holes P3. The third perforation hole P3 may have a width of about 80 μm to about 200 μm, but the embodiment is not limited thereto.

The solar cell according to the embodiment further includes the barrier layer 700 interposed between the substrate 100 and the back electrode layer 200. Due to the barrier layer 700, the ohmic layer 800, which will be described later, is formed only on a part of the back electrode layer 200. That is, the barrier layer 700 can prevent diffusion of sodium generated from the substrate 100.

The barrier layer 700 is formed between the substrate 100 and the back electrode layer 200. The barrier layer 700 can be formed in the back electrode layer 200. In detail, the barrier layer 700 can be formed at the interfacial surface between the substrate 100 and the back electrode layer 200.

In addition, the barrier layer 700 can be formed on a region of the back electrode layer 200, which corresponds to the second perforation hole P2 formed in the light absorbing layer 300. In detail, the barrier layer 700 can be formed on a region between the second perforation hole P2 and the third perforation P3.

The barrier layer 700 may include SiO2 or SiO4. In addition, referring to FIG. 3, the length L2 of the barrier layer 700 is in the range of ⅓ to ⅔ based on the length L1 of the back electrode layer 200. In addition, the thickness T3 of the barrier layer 700 is in the range of ⅕ to ⅓ based on the thickness T1 of the back electrode layer 200.

Further, the solar cell according to the embodiment may include the ohmic layer 800 selectively formed between the back electrode layer 200 and the light absorbing layer 300.

As shown in FIG. 3, the ohmic layer 800 can be formed in the back electrode layer 200. In detail, the ohmic layer 800 can be formed at an upper portion in the back electrode layer 200. In more detail, the ohmic layer 800 can be formed at the interfacial surface between the back electrode layer 200 and the light absorbing layer 300. In addition, the ohmic layer 800 can be formed on a part of an upper portion of the back electrode layer 200 such that the ohmic layer 800 may not correspond to the second perforation hole P2 formed in the light absorbing layer 300.

Further, referring to FIGS. 2 and 3, the barrier layer 700 may partially overlap with the ohmic layer 800 (see, D in FIG. 3), but the embodiment is not limited thereto. That is, as shown in FIG. 1, the barrier layer 700 may be disposed without overlapping with the ohmic layer 800.

The ohmic layer 800 may be formed by using a compound including Mo and Se. For instance, the ohmic layer 800 may include MoSe2, but the embodiment is not limited thereto.

The ohmic layer 800 may be naturally formed when the CIGS compound of the light absorbing layer 300 is simultaneously deposited on the back electrode layer 200. In addition, the formation of the ohmic layer 800 may be promoted by the sodium component contained in the substrate 100. That is, the sodium component contained in the substrate 100 may promote the combination and production of the Se component of the light absorbing layer 400 and the Mo component of the back electrode layer 200.

FIGS. 4 and 5 are sectional views showing the function of the barrier layer 700 according to the embodiment. As shown in FIG. 4, when the light absorbing layer 300 is formed on the back electrode layer 200, the sodium component contained in the substrate 100 is moved toward the back electrode layer 200. At this time, the sodium component existing in the lower portion (A region) of the barrier layer 700 is not moved due to the barrier layer 700.

In contrast, the sodium component existing in a region (B region) where the barrier layer 700 is not formed can be easily moved to the upper portion of the back electrode layer 200. Thus, the amount of the sodium component moved to the back electrode layer 200 from the A region is smaller than the amount of the sodium component moved to the back electrode layer 200 from the B region.

For this reason, the amount of the sodium component of the substrate 100 combined with the Se component contained in the light absorbing layer 300 may vary depending on the regions of the back electrode layer 200. That is, as shown in FIG. 5, the ohmic layer 800 can be formed on the B region of the back electrode layer 200 with a heavy thickness. In contrast, the ohmic layer 800 may not be formed on the A region of the back electrode layer 200 or formed with a thin thickness. Of course, the sodium component of the substrate 100 can be combined with the Se component contained in the light absorbing layer 300 in the A region. However, the amount of the sodium component combined with the Se component in the A region is very small, so the thickness of the ohmic layer 800 is very thin.

In detail, according to the solar cell of the embodiment, the ohmic layer 800 is formed on a part of the upper portion of the back electrode layer 200 in such a manner that the ohmic layer 800 may not correspond to the second perforation hole P2 formed in the light absorbing layer 300 by the barrier layer 700.

FIGS. 6 to 13 are sectional views showing the manufacturing procedure for the solar cell according to the embodiment. The description about the manufacturing procedure for the solar cell will be made based on the description about the solar cell. The description about the solar cell will be incorporated herein as a reference.

Referring to FIGS. 6 and 7, the barrier layer 700 is formed on the substrate 100. The barrier layer 700 can be formed by depositing the barrier layer 700 on the substrate 100 and then patterning the barrier layer 700 into several parts. The patterning process may include a laser scribing process, a wet etching process or a dry etching process.

For instance, the soda lime substrate 100 including sodium is prepared and the barrier layer 700 is deposited on one surface of the substrate 100. The barrier layer 700 can be formed through a chemical vapor deposition process or a sputtering process and may have a thickness in the range of about 0.2 μm to about 0.6 μm. In detail, the barrier layer 700 may have a thickness in the range of about 0.2 μm to about 0.3 μm.

Referring to FIG. 8, the back electrode layer 200 is formed on the substrate 100 and the barrier layer 700. The back electrode layer 200 can be formed through a PVD (physical vapor deposition) process or a plating process. In addition, an additional layer, such as a diffusion barrier layer, can be interposed between the substrate 100 and the back electrode layer 200.

After that, as shown in FIG. 9, the back electrode layer 200 is patterned to form the first perforation holes P1 such that the barrier layer 700 can be positioned at a predetermined region of the back electrode layer 200.

Referring to FIG. 10, the light absorbing layer 300 is formed on the back electrode layer 200. At the same time, the ohmic layer 800 is formed between the back electrode layer 200 and the light absorbing layer 300.

That is, when the light absorbing layer 300 is formed, the Se component contained in the light absorbing layer 300 is combined with the sodium component contained in the soda lime substrate 100 so that the ohmic layer 800 is formed between the back electrode layer 200 and the light absorbing layer 300. In addition, as shown in FIGS. 4 and 5, the ohmic layer 800 is selectively formed on a predetermined region of the top surface of the back electrode layer 200 due to the barrier layer 700.

Then, referring to FIG. 11, the buffer layer 400 and the high-resistance buffer layer 500 are formed on the light absorbing layer 300. The buffer layer 400 can be formed by depositing CdS on the light absorbing layer 300 through the chemical bath deposition (CBD) process.

The high-resistance buffer layer 500 is disposed on the buffer layer 400. The high-resistance buffer layer 500 includes i-ZnO which is not doped with impurities. The high-resistance buffer layer 500 may have the energy bandgap in the range of about 3.1 eV to 3.3 eV. In addition, the high-resistance buffer layer 500 can be omitted.

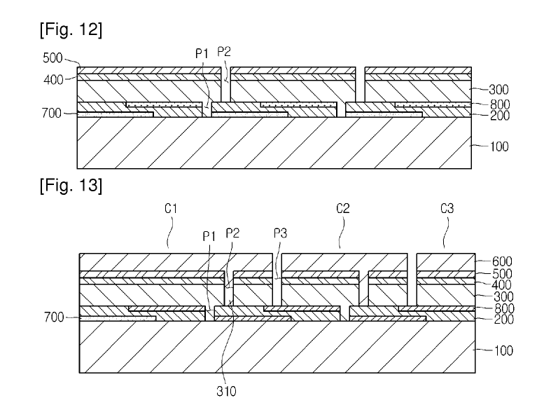

After that, as shown in FIG. 12, the second perforation holes P2 are formed through the high-resistance buffer layer 500, the buffer layer 400 and the light absorbing layer 300. The second perforation holes P2 are spaced apart from the first perforation holes P1 by a predetermined distance. The second perforation holes P2 can be formed through the mechanical scheme or laser irradiation scheme. For instance, the second perforation holes P2 can be formed through the scribing process. The second perforation holes P2 may not correspond to the ohmic layer 800.

Referring to FIG. 13, the window layer 600 is formed on the high-resistance buffer layer 500. The window layer 600 can be formed by depositing transparent conductive materials on the high-resistance buffer layer 500. At this time, the transparent conductive materials are filled in the second perforation hole P2 so that the connection wire 310 can be formed.

The connection wire 310 electrically connects the window layer 600 with the back electrode layer 200. As mentioned above, the second perforation hole P2 having the connection wire 310 may not correspond to the ohmic layer 800. Thus, the window layer 600 can be electrically connected to the back electrode layer 200 having contact resistance higher than that of the ohmic layer 800 so that the efficiency of the solar cell can be improved.

Then, the third perforation holes P3 are formed through the window layer 600, the high-resistance buffer layer 500, the buffer layer 400 and the light absorbing layer 300. The third perforation holes P3 are spaced apart from the second perforation holes P2 by a predetermined distance.

Due to the third perforation holes P3, the solar cells C1, C2, C3 . . . Cn including the back electrode layer 200, the light absorbing layer 300, the buffer layer 400 and the high-resistance buffer layer 500 can be formed. In detail, the solar cells C1, C2, C3 . . . Cn are divided from each other by the third perforation holes P3.

The third perforation holes P3 can be formed through the mechanical scheme or the laser irradiation scheme such that the top surface of the back electrode layer 200 can be exposed through the third perforation holes P3.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a substrate;
a back electrode layer on the substrate;
a light absorbing layer including a second perforation hole on the back electrode layer;
a window layer on the light absorbing layer; and
a barrier layer between the substrate and the back electrode layer.

2. The solar cell of claim 1, further comprising an ohmic layer between the back electrode layer and the light absorbing layer.

3. The solar cell of claim 2, wherein the ohmic layer includes MoSe₂.

4. The solar cell of claim 2, wherein the ohmic layer is disposed corresponding to a region where the second perforation hole is not formed.

5. The solar cell of claim 1, wherein the barrier layer prevents sodium diffusion.

6. The solar cell of claim 1, wherein the barrier layer is formed at a region corresponding to the second perforation hole.

7. The solar cell of claim 1, wherein the barrier layer has a width corresponding to ⅓ to ⅔ based on a width of the back electrode layer.

8. The solar cell of claim 1, wherein the barrier layer has a thickness corresponding to ⅕ to ⅓ based on a thickness of the back electrode layer.

9. The solar cell of claim 1, wherein the barrier layer includes SiO₂ or SiO₄.

10. A method of manufacturing a solar cell, the method comprising:
forming a barrier layer on a substrate;
forming a back electrode layer on the substrate and the barrier layer;
forming a light absorbing layer on the back electrode layer and forming an ohmic layer between the back electrode layer and the light absorbing layer; and
forming a window layer on the light absorbing layer.

11. The method of claim 10, wherein the forming of the back electrode layer includes patterning the back electrode layer to form a first perforation hole.

12. The method of claim 10, wherein the forming of the light absorbing layer includes patterning the light absorbing layer to form a second perforation hole.

13. The method of claim 12, wherein the ohmic layer is disposed such that the ohmic layer does not correspond to the second perforation hole.

14. The method of claim 10, wherein the barrier layer has a thickness in a range of about 0.2 μm to about 0.3 μm.

15. A solar cell module comprising:
a plurality of solar cells,
wherein each solar cell comprises:
a back electrode layer including a first perforation hole on a substrate;
a light absorbing layer including a second perforation hole on the back electrode layer;
a window layer on the light absorbing layer;
a barrier layer between the substrate and the back electrode layer; and
an ohmic layer between the back electrode layer and the light absorbing layer.

16. The solar cell module of claim 15, wherein the solar cells are divided from each other by a third perforation hole.

17. The solar cell module of claim 16, wherein the barrier layer is disposed corresponding to a region between the second perforation hole and the third perforation hole.

18. The solar cell module of claim 15, wherein the substrate includes active areas where the solar cells are disposed and non-active areas disposed between the active areas.

19. The solar cell module of claim 18, wherein the barrier layer is disposed corresponding to the non-active areas, and the ohmic layer is disposed corresponding to the active areas.
